(19) United States
(12) Patent Application Publication
(10) Pub. No.: US 2009/0045720 A1
(43) Pub. Date: Feb. 19, 2009

(54) Method for producing nanowires using porous glass template, and multi-probe, field emission tip and devices employing the nanowires

(76) Inventors: Eun Kyung Lee, Suwon-si (KR); Byoung Lyong Choi, Seoul (KR); Jong Min Kim, Suwon-si (KR); Soon Jae Kwon, Seongnam-si (KR); Kyung Sang Cho, Gwacheon-si (KR); Jae Ho Lee, Yongin-si (KR)

Correspondence Address: CANTOR COLBURN, LLP, 20 Church Street, 22nd Floor, Hartford, CT, 06103, US

(21) Appl. No.: 11/449,230

(22) Filed: Jun. 8, 2006

(30) Foreign Application Priority Data
Nov. 10, 2005 (KR) 10-2005-0107443
Apr. 18, 2006 (KR) 10-2006-0034947
Apr. 21, 2006 (KR) 10-2006-0036130

(51) Int. Cl. H01J 1/62; H01J 1/02; H01L 21/28

(52) U.S. Cl. 313/503; 313/309; 438/20; 257/E21.158

(57) ABSTRACT

Disclosed herein is a method for producing nanowires, which features the use of a porous glass template in combination with a solid-liquid-solid or vapor-liquid-solid process for growing nanowires which are highly straight and have nanoparticles precisely arranged therein. The nanowires can be grown into composite structures of superlattices and hybrids by modulating the composition of the materials provided thereto. Also disclosed is the use of the nanowires in multi-probes, field emission tips, and devices.

### CROSS-REFERENCE TO RELATED PATENT APPLICATIONS

This application claims priority to Korean Patent Application No. 10-2005-0107443, filed on Nov. 11, 2005; Korean Patent Application No. 10-200640034947, filed on Apr. 18, 2006; and Korean Patent Application No. 10-2006-0036130, filed on Apr. 21, 2006 in the Korean Intellectual Property Office, the disclosures of which are incorporated herein in their entireties by reference.

### BACKGROUND OF THE INVENTION

1. Field of the Invention

The present invention relates to a method for producing nanowires using a porous glass template, and the nanowires. More particularly, the present invention relates to a method for producing nanowires using a porous glass template in combination with a solid-liquid-solid (SLS) or a vapor-liquid-solid (VLS) technique, and nanowires which are grown in highly straight directions and have nanoparticles well arranged therein. Also, the present invention is concerned with a multi-probe, a field emission tip, and a device, all comprising the nanowires.

2. Description of the Related Art

Nanowires are defined as structures that have a lateral size constrained on the order of nanometers (1 nm=10⁻⁹ m) and an unconstrained longitudinal size on the order of hundreds of nanometers, micrometers (1 μm=10⁻⁶ in), or millimeters (1 mm=10⁻³ m). The properties of nanowires depend on the diameter and length thereof. Thanks to their small size, nanowires find various applications in micro-scale elements. For example, nanowires can utilize properties of electrons migrating in certain directions or optical properties leading to polarization.

Whereas extensive and active research is now being made into the physical properties and methods of producing nanoparticles, nanowires have received little study. Methods of producing nanowires are typified by chemical vapor deposition (CVD) methods, laser ablation methods, and template methods.

In a template method, pores on the order of nanometers to hundreds of nanometers are constructed and used as templates for individual nanowires. For instance, an aluminum electrode is covered with aluminum oxide through surface oxidation, followed by electrochemically etching the oxide to form nanopores. The application of an electric field to a metal ion solution in which the aluminum electrode is immersed causes the metal ions to be stacked on the aluminum electrode, thereby filling the pores with metal ions. Then, the simple removal of the oxides leaves the metal nanowires thus formed.

However, these conventional methods for producing nanowires using a template can be complicated and require too much time to be applied for mass production. In addition, they can suffer from the disadvantage of being unable to produce highly straight and precisely arranged nanowires.

A nanowire producing method using a template is disclosed in U.S. Pat. No. 6,525,461, and is characterized by providing a substrate having a catalyst film and a porous layer, and thermally treating the substrate to form titanium nanowires in narrow pores. Aluminum for an anodic aluminum oxide (AAO) template cannot be used for the production of nanowires through an SLS process due to the melting point of 660 degrees Celsius (° C.). Also, the template cannot be applied for the production of optical elements because it is not transparent.

Meanwhile, a nano-imprint process, known as a kind of VLS process, has been reported to grow a highly straight nanowire (see e.g., Nanoletter 2005, Vol. 5, No. 4, p 458). The nanowires obtained through this process, however, can have low linear densities and a large diameter of 40 nm or greater, and can be non-uniform in length and diameter.

The quantity of electrons emitted from an electron emitter is affected by the electric field applied thereto and by the material and shape of the electron emitter. The electric field typically applied has decreased from hundreds of volts to tens of volts. This tendency toward the use of lower voltages causes scientists to focus on the development of the material and shape of the electron emitter.

Field emission at solid phase surfaces is an important physical property based on which various electromagnetic devices including field emission flat displays, vacuum microelectronic devices, and microwave devices have been developed.

One of the most important and fundamental parts for the application of such electromagnetic device is a field emission portion. Thus, the field emission portion is required to allow a large quantity of electrons to be readily and stably emitted even in the presence of a low electric field, in addition to being highly durable.

Conventional nano-size field emission tips, such as carbon nanotubes, are blunted as they are used. For this reason, materials having high strength, such as ZnO, Si, and SiC, are rising as a substitute for soft tips.

### SUMMARY OF THE INVENTION

Accordingly, the present invention has been made keeping in mind the above problems occurring in the prior art, and an aspect of the present invention includes providing a method for producing highly straight nanowires with nanoparticles well arranged therein, to readily controlled diameters and lengths thereof.

Another aspect of the present invention includes providing a multi-probe, which can be readily controlled with regard to size, length, and density in a nanoscale.

Another aspect of the present invention includes providing a field emission tip, which can be readily controlled with regard to size, length, and density on a nanoscale.

Still another aspect of the present invention includes providing a device comprising the nanowires, which are highly straight and have nanoparticles well arranged therein.

Still another aspect of the present invention includes providing a device comprising the field emission tip.

In accordance with an exemplary embodiment of the present invention, provided is a method for producing nanowires, which comprises providing a porous glass template; placing the template on a substrate coated with a metal catalyst layer; and growing nanowires along pores within the template trough an solid-liquid-solid (SLS) process or a vapor-liquid-solid (VLS) process.

In accordance with another exemplary embodiment of the present invention, provided is a multi-probe, which is fabricated by selectively etching the terminal portion of the template so as to expose the nanowires or by growing the nanowires to a length greater than that of the template so as to expose the nanowires.

In accordance with another exemplary embodiment of the present invention, provided is a field emission tip, which is fabricated by selectively etching the terminal portion of the template so as to expose the nanowires or by growing the nanowires to a length greater than that of the template so as to expose the nanowires.

In accordance with still another exemplary embodiment of the present invention, provided is a device comprising nanowires that are highly straight and have precisely arranged nanoparticles.

In accordance with still another exemplary embodiment of the present invention, provided is a device comprising a field emission tip, which can be readily controlled on a nanoscale with regard to size, length and density.

### BRIEF DESCRIPTION OF THE DRAWINGS

The present invention is best understood with reference to the accompanying drawings, in which like reference numerals are used for like and corresponding parts, wherein:

FIG. 1 is a schematic illustration showing a process of producing nanowires using a porous glass template in accordance with an embodiment of the present invention;

FIG. 2 is a schematic illustration showing the production of nanowires through a solid-liquid-solid (SLS) mechanism;

FIG. 3 is a schematic illustration showing the production of nanowires through a vapor-liquid-solid (VLS) mechanism;

FIG. 4 is a schematic illustration of an electroluminescent (EL) device according to an embodiment of the present invention;

FIG. 5 is a schematic illustration of methods for fabricating a multi-probe in different manners in accordance with embodiments of the present invention;

FIG. 6 is a schematic illustration showing a process of fabricating a multi-probe through a selective etching process in accordance with an embodiment of the present invention;

FIG. 7a is a schematic illustration of a principle of pore formation using an atomic force microscope (AFM) probe;

FIG. 7b is a photograph of a pattern formed using an AFM equipped with a multi-probe;

FIG. 8a is a photograph of a mono-probe cantilever;

FIG. 8b is a photograph of a multi-probe cantilever;

FIG. 9 is a schematic illustration showing the use of the multi-probe according to the present invention as an AFM probe;

FIG. 10 is a schematic illustration showing a switching device according to an embodiment of the present invention; and

FIG. 11 is a schematic view illustrating the operation principle of a switching device according to the present invention, in an OFF-state (a) and in an ON-state (b).

### DETAILED DESCRIPTION OF THE INVENTION

A detailed description is given of the present invention with reference to the accompanying drawings.

The method for producing nanowires in accordance with the present invention features the use of a nano-porous glass template in the formation of nanowires by way of solid-liquid-solid (SLS) or vapor-liquid-solid (VLS) phase growth.

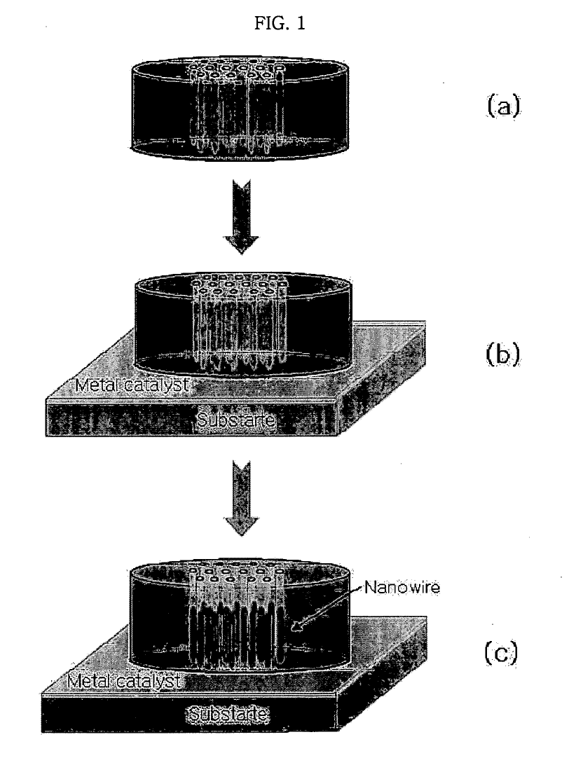

FIG. 1 schematically shows the method for producing a nanowire using a porous glass template in accordance with the present invention. As seen in FIG. 1, a porous glass template is provided (a) and a template is placed on a substrate coated with a metal catalyst layer (b), followed by forming nanowires along pores within the template through SLS or VLS growth (c).

It is easy to control the sizes and lengths of the pores of the glass template, and the gaps therebetween. Thus, the porous glass template allows nanowires to be readily produced and allows convenient control of the diameter and length thereof. In addition, composite structures, such as superlattices and hybrids, can be formed by modifying the component or composition of the nanowire. The presence of dopants during nanowire growth results in doped nanowires.

Below, the production method of the present invention is described in more detail.

Featuring the use of a glass template, as described above, the present invention pertains to the production of nanowires. The template useful in the present invention contains a plurality of pores, that is, hollow portions in which nanowires are to be grown. The template may be made from a material selected from a group consisting of glass, silica, and a metal oxide such as TiO₂, ZnO, SnO₂, and WO₃.

Conventionally, anodic aluminum oxide (AAO) has been widely used as a template for producing nanowires. However, an AAO template makes it difficult to form pores uniformly and at desired positions because pore sizes and lengths of the template are controlled with applied voltages. In addition, when etching is not conducted to the end of the lengthwise direction, poreless portions must be removed, which makes the processes complicated. Moreover, aluminum present inside the AAO template has a melting point of 660 degrees Celsius (° C.), which is too low to grow wires through an SLS process, which is conducted at higher temperatures. Due to the lack of transparency, the AAO template cannot be used for the production of optical elements.

In contrast, the glass template of the present invention is constructed by extending a bundle of fibers concurrently, so that it is easy to form pores uniformly over the template and at desired positions. In addition, since the length of the template is determined merely by cutting the fibers, templates having uniform pores can be produced at various lengths. Not only is the method simple, but also the melting point of glass, which can be as high as about 1,700° C., allows an SLS process to be applied for the growth of the wire. Moreover, the material is transparent, so that it can be applied to optical devices. Further, optical fiber techniques, which have greatly advanced, can be utilized.

The porous glass template has high degrees of freedom with respect to diameter and height, so that the dimensions of the template can be freely selected according to the size of the substrate on which the nanowire is grown. Depending on the dimension of the nanowire to be produced, the size of the pores within the porous template is not specifically limited.

After being provided, the glass template is placed on a substrate coated with a metal catalyst layer. The metal catalyst layer is preferably made by applying, for example, an Au metal catalyst on a substrate. The substrate may be washed, in advance, to remove impurities therefrom.

Exemplary substrates useful in the present invention are a silicon substrate and a silicon-coated glass substrate.

If able to grow nanowires, any metal catalyst may be used. Examples of metal catalysts useful in the present invention include Au, Ni, Fe, Ag, Pd, and Pd/Ni, but are not limited thereto.

The metal catalyst may be layered in the form of nanoparticles or a thin film on the substrate. The metal catalyst layer thus formed is preferably 50 nanometers (nm) thick or thinner.

Methods of depositing the metal catalyst on the substrate are not specifically limited, and may be techniques known in the art, such as chemical vapor deposition (CVD), sputtering, electronbeam evaporation, vacuum deposition, spin coating, dipping, and the like.

The growth of the nanowires within the pores of the template can be achieved using an SLS or VLS process.

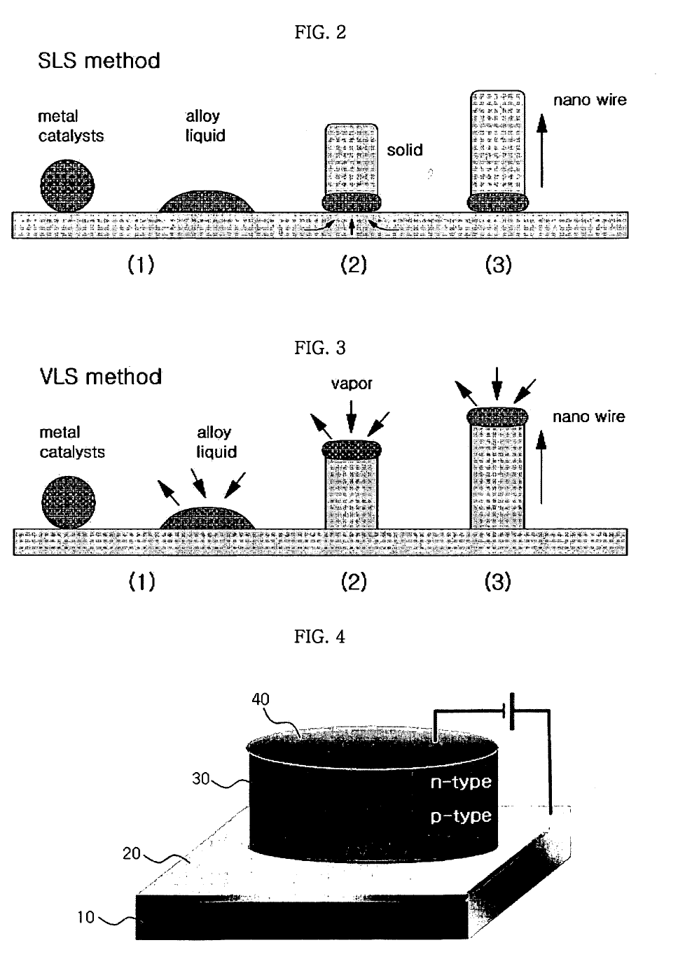

According to an SLS process, as illustrated in FIG. 2, the silicon, which is not provided separately in a vapor phase, but is diffused from the solid substrate (e.g., silicon substrate), is condensed on the surface of the melted catalyst and crystallized into a nanowire.

On the other hand, a VLS process, as shown in FIG. 3, utilizes vapor phase silicon-containing species which are transferred into a high-temperature furnace and condensed on the surface of a melted catalyst, such as gold, cobalt, nickel, etc., followed by crystallization into silicon nanowires.

In more detail, the SLS process can be performed by heating the template-carrying substrate in a furnace with gas provided thereto, so as to form nanowires from a nanowire source diffused from the substrate. Optionally, force may be applied so as for the metal on the substrate to be included inside the nanowires upon growth.

Aiming to modify gaps between growing nanodots to endow the nanowires with various physical properties, the application of force can be performed by orienting the surface from which nanowires grow downwards, so as to take advantage of gravity. In addition, an electric field or a mechanical force may be used.

The VLS process may be conducted by heating the template-carrying substrate in a furnace, with gas and a nanowire source introduced thereinto, to grow nanowires.

Gases useful in the SLS or the VLS process may be selected from, but are not limited to, the group consisting of Ar, N₂, He, and H₂. The gas may be introduced at a rate of 100 standard cubic centimeters (sccm), or at different rates depending on the process.

The SLS process or the VLS process may be conducted under a pressure of 760 torr or less. As for temperature, it is 800 to 1200° C. for the SLS process, and 370 to 600° C. for the VLS process when using a gold catalyst. The time period for heating may vary with the length of the nanowire grown.

As a nanowire source introduced in the VLS process, SiH₄, SiCl₄, or SiH₂Cl₂may be used for silicon nanowires.

In addition, impurities may be incorporated to afford doped nanowires. The compositional modification of source materials can lead to the formation of composite structures, such as superlattices and hybrids. The composite structures may be obtained by employing a Group III-V compound (for example, gallium arsenide (GaAs), gallium nitride (GaN)), carbon nanotubes (CNT), zinc oxide (ZnO), and/or silicon carbide (SiC), in the case of silicon nanowires.

Template-free nanowires can be obtained by removing the template with an etchant such as hydrofluoric acid.

The method for producing nanowires in accordance with the present invention may be modified in various ways.

Once formed using the above-mentioned processes, the nanowires, as shown in FIG. 5, are partially exposed by removing the terminal portion of the template with etchant (FIG. 5b) or through additional extension over the template (FIG. 5a).

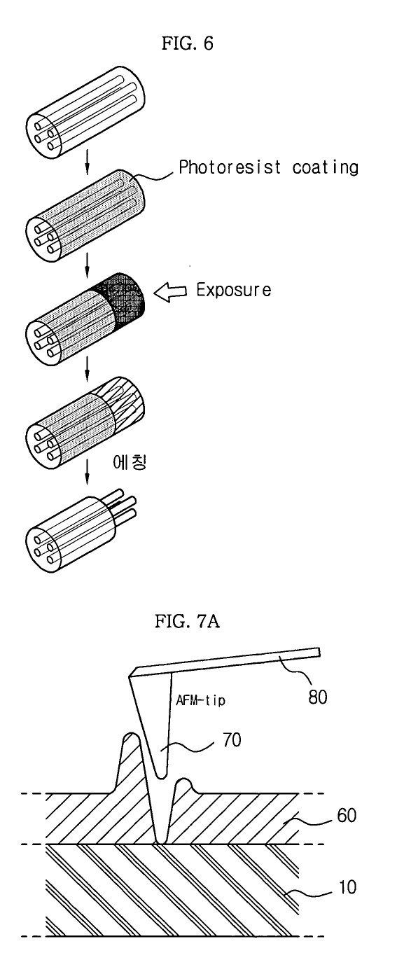

With reference to FIG. 6, a process of etching the terminal part of the template is illustrated. First, the template is coated with a photoresist composition, and the region to be etched is exposed to light. Since the region to be exposed is not planar, but is a three-dimensional structure, a pulsed-laser having a narrow line width can be used to accomplish elaborate and fine exposure. Following the exposure, the application of an etchant removes the exposed region of the template. The etching process may be carried out in a dry or wet manner. Instead of a chemical etching process, a photoetching process may be used to partially remove the template.

In a wet etching process, an etchant, such as an aqueous acetic acid, hydrofluoric acid, an aqueous phosphoric acid solution, or the like, is used to selectively remove the template. Using gas, plasma, or ion beams as etchant, a dry etching process is exemplified by reactive ion etching (RIE), in which a reactive gas in a plasma state is activated to undergo a chemical reaction with a target material with the production of volatile materials or by ICP-RIE, in which inductive coupled plasma (ICP) is used as an active source.

On the other hand, the growth of nanowires over the template can be achieved by controlling the reaction conditions of the VLS or SLS process. For example, because the growth of nanowires continues to occur in a VLS process as long as gas is provided, the maintenance of gas supply for a time period longer than that required for the growth to the length of the template results in the extension of the nanowires over the template.

A scanning probe microscope (SPM) is the general name for microscopes that can scan using probes to measure various physical parameters. Basically, an SPM includes a probe having a sharp tip, a scanner for scanning the probe on a specimen, and a control and signal processing system for controlling the probe and the scanner and processing the signals from them.

Scanning probe microscopy (SPM) has been developed into various technologies including scanning tunneling microscopy (STM) using the current flowing due to potential between the tip and the specimen, atomic force microscopy (AFM using various atomic forces between the tip and the specimen, magnetic force microscopy (MFM) using the magnetic force between a magnetic field of the specimen and a magnetized tip, scanning near-field optical microscopy) (SNOM) by which the resolution limit of visible wavelengths is overcome, and electrostatic force microscopy (EFM), which uses the electrostatic force between the specimen and the tip.

Atomic force microscopy, a branch of scanning probe microscopy, is one of the foremost tools for obtaining three-dimensional information on material surfaces, in which a material surface is scanned in a two-dimensional manner with the probe to produce three-dimensional information about the surface.

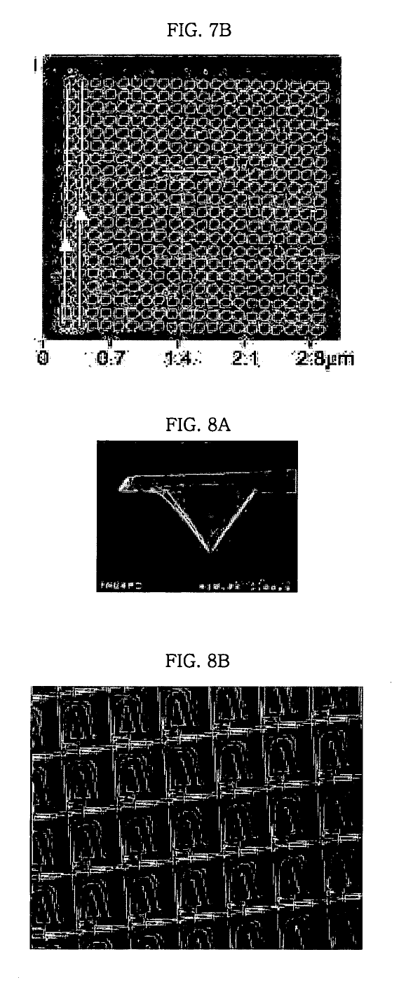

Besides being used for analysis, an AFM probe can be a tool for forming pores in a planar substrate. FIG. 7a is a schematic illustration showing the use of an AFM probe in forming a pore. As seen in FIG. 7a, if a tip 70 provided to an AFM probe is forced to move up and down, a pore can be formed to a desired depth in a mask 60 on a substrate 10. In this way, AFM probes may be utilized for nano-patterning. FIG. 7b is a photograph of a pattern formed using an AFM multi-probe (photo obtained from International Business Machines or IBM). The patterning depends on the size and shape of the tip 70.

FIG. 8a is a photograph showing a single probe cantilever available for patterning and FIG. 8b is a photograph showing a multi-probe cantilever in which a plurality of probes are arrayed two-dimensionally (photos obtained from IBM).

In order to detect surface electrons on the order of tens of nanometers and improve processing speeds using an SPM, an array of probes is fabricated. Conventional probes are usually made from silicon or carbon nanotubes. In the case of carbon nanotubes, they can be fabricated into tips on the scale of nanometers, but suffer from the disadvantage of low yield and high cost. On the other hand, it is substantially impossible to fabricate a tip on the nanoscale from silicon. Currently, multi-probes are constructed using lithography or tip etching, but a technology capable of freely controlling gaps, sizes, and lengths of tips on the nanoscale has not yet been introduced.

In accordance with the present invention, nanowires are grown using a glass template containing a plurality of pores and are utilized for fabricating an array of multi-probes on the order of tens of nanometers. The feasibility of controlling the dimensions of the template leads to controlling the tip gap, length, size, and density of the multi-probes on the nanoscale.

The multi-probe obtained in accordance with the present invention can be applied to AFM, which requires a multi-probe having a plurality of probes arranged one- or two-dimensionally. Instead of being used for electric/magnetic analysis, the multi-probe fabricated in accordance with the present invention may be used to form pores in a mask layer at a desired size and density. With reference to FIG. 9, a multi-probe fabricated in accordance with the present invention is shown in use as an AFM probe.

With the multi-probe of the present invention, electric/magnetic analysis or nanopatterning can be conducted at significantly improved speeds and efficiencies. For instance, the multi-probe of the present invention can solve the problem of low AFM throughput occurring when a conventional AFM probe is used.

After the partially exposed nanowires are further adjusted to have uniform sizes, they can be used as field emission tips on various size scales.

In accordance with another embodiment, the present invention pertains to a field emission tip, prepared from the nanowires of the present invention, which can be readily adjusted with respect to position and size and seldom becomes blunt, unlike conventional field emission tips such as carbon nanotubes.

In accordance with a further aspect, the present invention pertains to an electronic device comprising nanowires that can grow in a highly straight manner and be arrayed at desired positions.

Examples of the devices to which the nanowires of the present invention are applicable include electronic devices, such as a field effect transistor (FET), sensors, photodetectors, light emitting diodes (LEDs), laser diodes (LDs), electroluminescence devices (ELs), photoluminescence devices (PLs), and cathodeluminescence devices (CLs), but are not limited thereto.

Below, an EL device will be described in more detail.

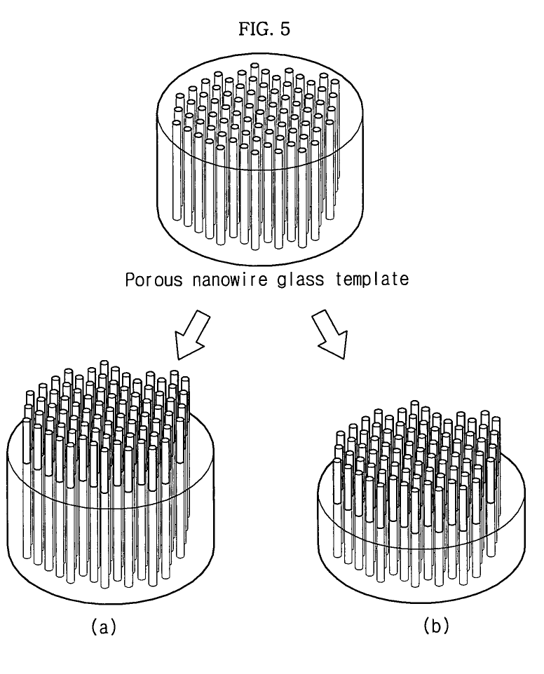

FIG. 4 schematically shows an EL device according to an embodiment of the present invention. As seen in FIG. 4, the EL device comprises a substrate 10; a first electrode layer 20; a porous template 30 with nanowires grown in pores thereof; and a second electrode layer 40. Although shown to be positioned on top of the substrate in FIG. 4, the first electrode layer may be formed beneath the substrate.

When nanowires produced using a conventional method are applied to an EL device, they do not assure emission in a straight direction, and require another material for filling the space between the nanowires, making the application thereof difficult. In contrast, as soon as they are produced, the nanowires of the present invention can be applied for the formation of electrodes because the template is transparent in the visible range, thereby allowing an EL device to be fabricated in a simple process and at low cost.

When doped with type or n-type impurities or p-n doped, the nanowires exhibit diode properties. For the substrate 10, the first electrode layer 20, and the second electrode layer 40, materials used in conventional EL devices may be used in a typical manner.

In accordance with still a further aspect, the present invention pertains to a device comprising the field emission tip of the present invention. Examples of devices to which the field emission tip is applicable include electronic devices, such as FETs, sensors, photodetectors, LEDs, LDs, ELs, PLs, CLs, and switching devices, but are not limited thereto.

Below, a switching device is described in more detail.

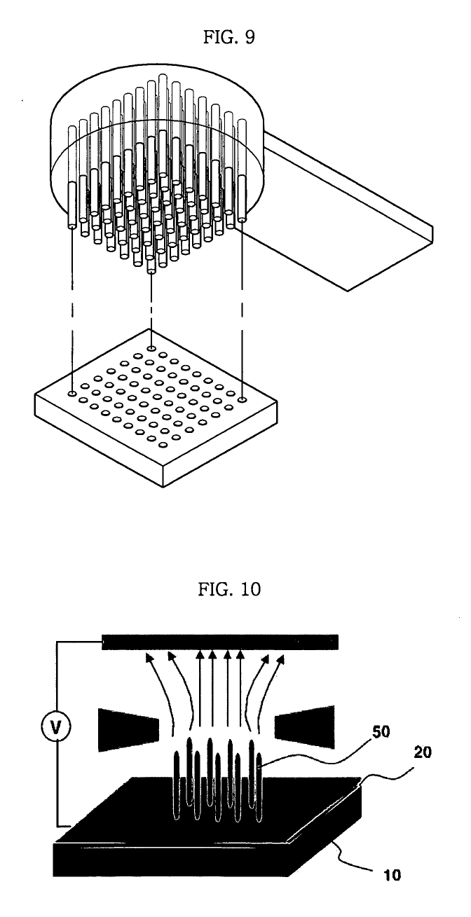

FIG. 10 is a schematic view showing a switching device according to an embodiment of the present invention. As shown in FIG. 10, the switching device comprises a substrate 10; a metal electrode layer 20; and nanowires 50, in which the metal electrode layer, although shown to be positioned on the substrate, may be formed beneath the substrate.

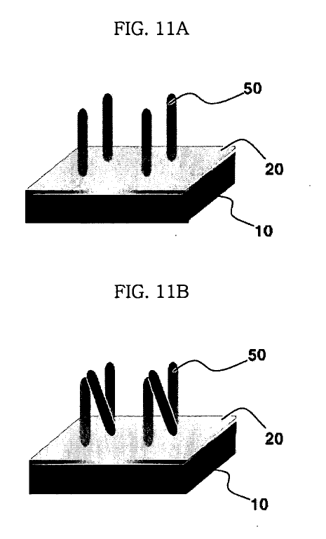

FIG. 11 schematically illustrates the operation principle of the switching device in an OFF-state (a) and in an ON-state (b). In a pair of tips, as shown in FIGS. 11a and 11b, a source electrode is formed at one tip while a drain electrode is formed at the other tip. When a gate electrode is applied, an electrostatic force or a van der Waals force is exerted between the two tips according to the voltage of the gate electrode. When the van der Waals force is predominant over the electrostatic force, the tips are caused to adhere to each other, forming an ON state. On the other hand, an electrostatic force larger than the van der Waals force causes the two tips to be separated, forming an OFF state. That is, the switching device takes advantage of this phenomenon.

The electrode may be formed between the lower portion of the tip and the substrate or on the surface of the tips using a semiconductor process such as deposition

A better understanding of the present invention may be given with the following examples which are set forth to illustrate, but are not to be construed to limit the present invention.

### EXAMPLE 1

### Production of Nanowires (1)

Following the removal of spontaneous oxides from a p-doped silicon substrate using an organic detergent and hydrofluoric acid, Au nanoparticles, serving as catalysts, commercially available from Nipponpaint, were spin-coated to form a thin film about 10 nm thick. Subsequently, a glass template was placed on the substrate, which was then introduced into a furnace. The temperature of the furnace was increased at a rate of 10 to 15° C. per minute, and Ar was introduced at a speed of 100 sccm through a sieve, with the total process pressure maintained at 500 torr. When heated to the process temperature 1,000° C., the substrate was maintained thereat for 30 minutes so as to grow the nanowires, followed by slowly cooling the substrate to 700° C. to terminate the growth of the nanowires.

### EXAMPLE 2

### Production of Nanowires (2)

The same procedure as in Example 1 was conducted, with the exception that a 4% SiH₄ gas was further introduced at a speed of 100 sccm in addition to Ar gas, and the process temperature was set at 400° C.

### EXAMPLE 3

### Fabrication of Multi-Probe

The template of the nanowires produced in Example 1 was coated with a photoresist composition containing AZ1512, and a partial terminal region of the template was then exposed using a g-line stepper. The exposed region of the template was etched using a hydrofluoric acid solution to partially expose the microwires confined within the pores.

### EXAMPLE 4

### Fabrication of Field Mission Tip (1)

Following the removal of spontaneous oxides from a silicon substrate using an organic detergent and hydrofluoric acid, Au nanoparticles about 10 nm in size, serving as catalysts, commercially available from Nipponpaint, were spin-coated to form a thin film about 10 nm thick.

Subsequently, a glass template was placed on the substrate, which was then introduced into a furnace. The temperature of the furnace was increased at a rate of 10 to 15° C. per minute, and Ar was introduced at a speed of 100 sccm, with the total process pressure maintained at 500 torr.

When heated to the process temperature of 1,000° C., the substrate was maintained thereat for 30 minutes so as to grow nanowires, followed by slowly cooling the substrate to 700° C. to terminate the growth of nanowires.

While part of the glass template was masked, the exposed region was removed using hydrofluoric acid as an etchant so as to expose part of the nanowires. The resulting structure was used as a field emission tip.

### EXAMPLE 5

### Fabrication of Field Emission Tip (2)

A field emission tip in which nanowires were partially exposed from a glass template was fabricated in the same procedure as in Example 4, with the exception that a 4% SiH₄ gas was further introduced at a speed of 100 sccm in addition to Ar gas, and the process temperature was set at 400° C.

### EXAMPLE 6

### Fabrication of Field Emission Tip (3)

Following the removal of spontaneous oxides from a silicon substrate using an organic detergent and hydrofluoric acid, Au nanoparticles about 10 nm in size, serving as catalysts, commercially available from Nipponpaint, were spin-coated to form a thin film about 10 nm thick.

Subsequently, a glass template was placed on the substrate, which was then introduced into a furnace. The temperature of the furnace was increased at a rate of 10 to 15° C. per minute, and Ar was introduced at a speed of 100 sccm, with the total process pressure maintained at 500 torr.

After being heated to the process temperature of 1,000° C., the substrate was maintained thereat for 30 minutes so as to grow nanowires within the template, and then for a further 20 minutes so as to extend the nanowires over the template, followed by slowly cooling the substrate to 700° C. to terminate the growth of nanowires. The resulting structure was used as a field emission tip.

### EXAMPLE 7

### Field Emission Tip (4)

A field emission tip, in which nanowires were partially exposed from a glass template, was fabricated in the same procedure as in Example 6, with the exception that a 4% SiH4 gas was further introduced at a speed of 100 sccm in addition to Ar gas, and the process temperature was set at 400° C.

### EXAMPLE 8

### Fabrication of EL Device

The nanowires produced using the photolithographic process of Example 1 were placed on a glass substrate having tin-doped indium oxide (ITO) patterned thereon. Over the nanowires, Ti and Au were deposited, in order, to thicknesses of 20 nm and 100 nm, respectively, to form a negative electrode, thereby fabricating an EL device.

### EXAMPLE 9

### Fabrication of Switching Device

The nanowires produced using a photolithographic process in Example 1 were placed on a glass substrate having ITO patterned thereon. A pair of two tips was provided with a source electrode and a drain electrode, respectively. A gate electrode was formed separately, so as to fabricate a switching device.

As described hereinbefore, the method according to the present invention can readily produce nanowires to controlled diameters and lengths and at low cost, and the nanowires can be grown in a straight direction and have nanoparticles precisely arranged thereon.

Provided with the nanowires of the present invention, which can be readily modulated with regard to tip gap, length, size, and density by controlling the pore dimension of the template, a multi-probe can be used for nanopatterning and is also applicable to SPM, thereby greatly improving electromagnetic analysis.

Taking advantage of the nanowires of the present invention, a field emission tip can be controlled with regard to tip size and density and thus can find a variety of applications in the electric element field, including as FETs, sensors, photodetectors, LEDs, LDs, ELs, PLs, CLs, and switching devices.

Examples are described in terms of exemplary embodiments of present invention. However, it should be understood that this disclosure is not limited to the explicit description of the present invention. The description and the claims of the present invention are to be interpreted as covering all alterations and modifications that fall within the true scope of this invention.

1. A method for producing nanowires, comprising:
providing a porous glass template;
placing the porous glass template on a substrate coated with a metal catalyst layer;
growing nanowires along pores within the porous glass template through a solid-liquid-solid process or a vapor-liquid-solid process.

2. The method as set forth in claim 1, wherein the substrate is a silicon substrate or a silicon-coated glass substrate.

3. The method as set forth in claim 1, wherein the metal catalyst layer is made from a metal catalyst selected from a group consisting of Au, Ni, Fe, Ag, Pd, Pd/Ni, and combinations thereof.

4. The method as set forth in claim 3, wherein the metal catalyst is applied in the form of nanoparticles or a thin film onto a surface of the substrate.

5. The method as set forth in claim 1, wherein the metal catalyst layer is formed to a thickness of not more than 50 nanometers.

6. The method as set forth in claim 1, wherein the metal catalyst layer is applied to the substrate using a process selected from the group consisting of a chemical vapor deposition (CVD) process, a sputtering process, an electron-beam evaporation process, a vacuum deposition process, a spin coating process, and a dipping process.

7. The method as set forth in claim 1, wherein the solid-liquid-solid process comprises heating the template-mounted substrate in a furnace, with gas introduced into the furnace, to grow nanowires from a nanowire source diffused from the substrate.

8. The method as set forth in claim 7, wherein the solid-liquid-solid process comprises applying a force in order for the metal of the substrate to be included in the nanowires upon growth.

9. The method as set forth in claim 8, wherein the force is gravity, an electric field, or a mechanical force.

10. The method as set forth in claim 1, wherein the vapor-liquid-solid process comprises heating the template-mounted substrate in a furnace, with gas and a nanowire source introduced into the furnace, to grow nanowires.

11. The method as set forth in claim 7, wherein the gas is selected from the group consisting of Ar, N₂, He, and H₂.

12. The method as set forth in claim 10, wherein the heating is performed under a pressure of 760 torr or less at a temperature from 370 to 600 degrees Celsius for the vapor-liquid-solid process.

13. The method as set forth in claim 10, wherein the nanowire source is selected from the group consisting of SiH₄, SiCl₄ and SiH₂Cl₂.

14. The method as set forth in claim 1, wherein the nanowires are doped with dopants during growth.

15. The method as set forth in claim 1, wherein the nanowires are grown into composite structures of superlattices or hybrids thereof by modulating a composition of the materials provided.

16. The method as set forth in claim 1, wherein the nanowires are carbon nanotubes.

17. The method as set forth in claim 1, further comprising selectively etching a terminal portion of the template so as to expose the nanowires.

18. The method as set forth in claim 17, wherein the selectively etching comprises:
coating the template with a photoresist composition;
selectively exposing a predetermined region of the template; and
removing the exposed region of the template.

19. The method as set forth in claim 18, wherein the selectively etching is conducted in a wet etching manner or in a dry etching manner.

20. The method as set forth in claim 19, wherein the dry etching manner uses gas, plasma, and/or ion beams.

21. The method as set forth in claim 19, wherein the wet etching manner uses an aqueous acetic acid solution, hydrofluoric acid, or an aqueous phosphoric acid solution as an etchant.

22. The method as set forth in claim 1, wherein the nanowires are grown to a length longer than that of the template so as to be exposed externally.

23. A multi-probe, fabricated using the method of claim 17.

24. The multi-probe as set forth in claim 23, wherein the multi-probe is used in Atomic Force Microscopy.

25. A field emission tip, fabricated using the method of claim 17.

26. A device, comprising the nanowires produced using the method of claim 1.

27. The device as set forth in claim 26, wherein the device is selected from the group consisting of an electric device, a sensor, a photodetector, an light emitting diode, an laser diode, an electroluminescence device, a photoluminescence device, and a cathodeluminescence device.

28. The device as set forth in claim 27, wherein the electroluminescence device comprises a substrate; a first electrode layer; a porous template with nanowires grown along pores therein; and a second electrode layer.

29. The device as set forth in claim 28, wherein each of the nanowires is doped with p-type or n-type dopants or p-n doped so as to exhibit diode properties.

30. A device, comprising the field emission tip of claim 25.

31. The device as set forth in claim 30, wherein the device is selected from a group consisting of an electric source, a sensor, a photodetector, an light emitting diode, an laser diode), an electroluminescence device, a photoluminescence device, a cathodeluminescence device, and a switching device.

32. The method as set forth in claim 10, wherein the gas is selected from the group consisting of Ar, N₂, He, and H₂.

33. The method as set forth in claim 7, wherein the heating is performed under a pressure of 760 torr or less at a temperature from 800 to 1,200 degrees Celsius for the solid-liquid-solid process.

34. A multi-probe, fabricated using the method of claim 22.

35. A field emission tip, fabricated using the method of claim 22.
